(19) United States
(12) Patent Application Publication
(10) Pub. No.: US 2001/0052764 A1
(43) Pub. Date: Dec. 20, 2001

(54) Magnetic-field device for stimulating and/or supporting physical functions

(76) Inventor: Werner Siekmann, Hamburg (DE)

Correspondence Address: ST. ONGE STEWARD JOHNSTON & REENS, LLC, 986 BEDFORD STREET, STAMFORD, CT, 06905-5619, US

(21) Appl. No.: 09/771,288

(22) Filed: Jan. 26, 2001

Related U.S. Application Data
(63) Continuation of application No. PCT/DE99/02328, filed on Jul. 30, 1999.

(30) Foreign Application Priority Data
Jul. 30, 1998 (DE) 198 34 266.7

(51) Int. Cl. G01R 33/00

(52) U.S. Cl. 324/117 R

(57) ABSTRACT

What is described here is a magnetic-field device for stimulating and/or supporting physical functions such as the treatment of fractures, comprising

an energized coil that is so designed that the part of the body to be treated or stimulated, respectively, is exposed to the magnetic field generated by the coil, and

a power supply unit supplying the current that flows through the coil and including at least one switching element that performs a so-called phase control on at least one half-wave for controlling the current flowing through the coil.

The invention is characterised by the feature that a controller is provided which changes said at least one switching element periodically over between at least two power stages.

This is a continuation of pending international application PCT/DE99/02328 filed on Jul. 30, 1999 which designates the U.S.

### DESCRIPTION

1. Field of the Invention

The invention relates to a magnetic-field device for stimulating and/or supporting physical functions.

2. Prior Art

Magnetic-field devices are commonly known and are manufactured, for instance, by the company of mbs system Arno Fichtner, Germany. In these magnetic-field devices a unidirectionally rectified sinusoidal signal and a phase controller are employed to modulate the intensity of each half-wave. When a toroid with a winding is employed a magnetic field with a peak value of roughly 90 gauss is achieved.

For an explanation of all the particulars, which are not described here in more details, explicit reference is made to the known devices produced by the aforementioned company.

Moreover, magnetic-field devices are known, for example from the document WO 92/19317. In this magnetic-field equipment a rectangular signal is used to generate the magnetic field. A toroid with six windings and an air gap is used as coil. The peak value of the magnetic field of the devices manufactured by the Applicant filing this Application does not exceed the level of 20 gauss.

Independently of whether this equipment operates on sinusoidal signals or rectangular signals, all the known devices share the common aspect that they produce different results of treatment:

Whereas a very good result is achieved on some patients the treatment is distinctly less successful on other patients, without any reason for these differences being known from the pertinent literature.

### BRIEF DESCRIPTION OF THE INVENTION

The present invention is based on the finding that the different results of the treatment ought to be due to a setting of the intensity of the magnetic field, which is not adapted to the respective patient.

The present invention is based on the problem of improving a magnetic-field device for stimulating and/or supporting physical functions such as the treatment of fractures, by means of an energized coil that is so configured that the pat of the body to be treated or stimulated, respectively, is exposed to the magnetic field created by the coil, and a power supply unit supplying the current flowing through the coil, which device comprises a mains transformer and at least one switching element implementing a so-called phase control on at least one half-wave to control the current flowing through the coil, this improvement being made in a way that a uniform result of the treatment will be achieved.

One inventive solution to this problem is defined in Patent claim 1. Improvements of the invention are the subject matters of claims 2 et seq.

It has been found in accordance with the invention that it is hardly possible—and if so only with a great deal of experience—to find that setting of the intensity of the magnetic field, which is the optimum for the respective patient. For this reason a controller is provided in accordance with the invention that changes the at least one switching element over periodically between at least two power stages. As a result of the change-over between at least two power stages, which takes place preferably within an interval of a few seconds and of one second in particular, each patient is treated with a magnetic-field intensity that is the optimum for him or her—at least in approximation. It was a surprise to discover that due to the inventive commutation between at least two power stages the period of the treatment can be drastically reduced, compared against conventional equipment.

In correspondence with prior art it is possible in the inventive device, too, that merely one switching element is provided which switches only one half-wave of the sinusoidal current and which performs also the phase control function. This switching element may be a thyristor in particular.

The commutation between at least two, preferably three or more, power stages in accordance with the invention is preferably implemented by means of an additional pulse package control, which means a pulse package control superimposed on the phase control function, with the width of the pulse package equally preferably amounting to one second or less. At the highest power stage, in particular, the value may distinctly exceed the level of 20 gauss, which is implemented in a known device, and may become as high as 90 gauss and more.

It is, of course, also possible to vary the operating angle periodically, instead of operating on a superimposed pulse package control scheme.

It is moreover preferred that the mains transformer supplies an output voltage of 24 Volt because in such a case the device is touch-safe.

The coil may be a cylindrical coil or a torus coil with up to three windings, in a manner known per se, with all types—such as those known from prior art—being conceivable for a patient lying on a support or seated. It is, of course, possible that the coil surrounds either the patient completely or only the respective part of the patient's body.

In an improvement of the inventive device electromagnetic waves in the HF to microwave range, and particularly in the decimetre range, may be emitted in additional or as an alternative to produce a magnetic field, which electromagnetic waves support the treatment or may be used for supplementary treatment. The coil creating the magnetic field may emit the waves in the decimetre range as well.

To this end the inventive device may comprise a transmitter for transmitting the electromagnetic waves, which is controlled by the controller.

### BRIEF DESCRIPTION OF THE DRAWING

The invention will now be described in the following, without any restriction of the general inventive idea, by exemplary embodiments with reference to the drawing which explicit reference is made to with respect to the disclosure of all inventive particulars which are not explained in more details here. In the drawing:

FIGS. 1 to 3 show the output signals for three different power stages.

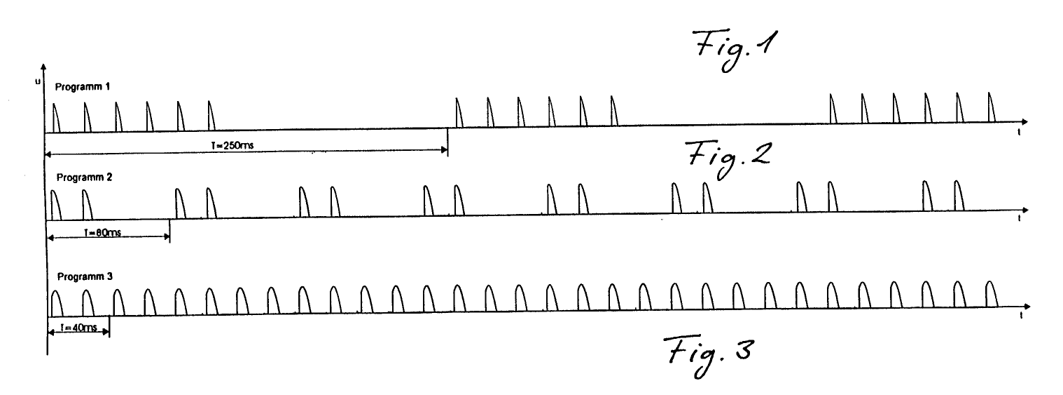

### DESCRIPTION OF EMBODIMENTS

The voltage or the current, respectively, that is applied to the coil producing the magnetic field, is represented as a function of time in a voltage/time diagram (U/t diagram) in the Figures. The device, that is not illustrated in details, may present a fundamental structure such as that present in the magnetic-field devices manufactured by the company of mbs system Arno Fichtner, Germany.

In the inventive device merely one switching element is provided, i.e. the thyristor that switches only one half-wave of the sinusoidal current, thus performing a phase control function.

The controller that controls the switching element—hence the thyristor in this embodiment—superimposes a so-called pulse package control on the phase control that is provided exclusively in the known equipment.

The Figure shows various possibilities of implementing the pulse package control function. The pulse package control function presents a pulse package width of 250 ms in the so-called “Programme 1” whereas the pulse package width is 80 ms in “Programme 2” and 40 ms in “Programme 3”.

It has been found in accordance with the present invention that it is not the mean intensity or power that is integrated over the defined period of time, which is decisive but that it is rather the fact that the magnetic field presents an instantaneous intensity that is periodically adapted repeatedly in an optimum manner to the respective patient, at least in approximation. As in the illustrated embodiment the intensity is commuted between at least two or more power stages—three in the illustrated embodiment—within intervals shorter than one second each patient is treated with the power stage representing an individualized optimum, without the physician responsible for the treatment being required to match or set the power level, respectively.

1. Magnetic-field device for stimulating and/or supporting physical functions such as the treatment of fractures, comprising
an energized coil that is so designed that the part of the body to be treated or stimulated, respectively, is exposed to the magnetic field generated by the coil, and
a power supply unit supplying the current that flows through the coil and including at least one switching element that performs a so-called phase control on at least one half-wave for controlling the current flowing through the coil,
characterised in that a controller is provided which changes said at least one switching element periodically over between at least two power stages.

2. Device according to claim 1,
characterised in that merely one switching element is provided that switches only one half-wave of the sinusoidal current.

3. Device according to claim 2,
characterised in that said switching element also performs the phase control function.

4. Device according to claim 2 or 3,
characterised in that said switching element is a thyristor.

5. Device according to any of the claims 1 to 4,
characterised in that additionally a pulse package control feature is provided for a periodic variation of the power.

6. Device according to claim 5,
characterised in that the change-over is performed between said at least two power stages between successive pulse packages.

7. Device according to claim 5 or 6,
characterised in that the width of a pulse package corresponds to one second or less.

8. Device according to any of the claims 1 to 7,
characterised in that said mains transformer supplies an output voltage of 24 Volt.

9. Device according to any of the claims 1 to 8,
characterised in that the coil is a cylindrical coil or a torus coil having up to three windings.

10. Device according to any of the claims 1 to 9,
characterised in that electromagnetic waves in the HF to micro-wave range and in the decimetre range in particular are emitted additionally or alternatively for creating a magnetic field.

11. Device according to claim 10,
characterised in that said coil emits the waves also in the decimetre range.

12. Device according to claim 11 or 12,
characterised in that the device comprises a transmitter for transmitting the electromagnetic waves, which transmitter is controlled by said controller.
